(19) United States
(12) Patent Application Publication
(10) Pub. No.: US 2014/0160709 A1
(43) Pub. Date: Jun. 12, 2014

(54) TUNER MODULE, CIRCUIT BOARD, AND METHOD FOR ASSEMBLING CIRCUIT BOARD

(71) Applicants: Tadashi Imai, Chiba (JP); Keisuke Yoshida, Aichi (JP); Kazunari Ueda, Aichi (JP); Toshiyuki Sudo, Tokyo (JP); Makoto Makishima, Saitama (JP)

(72) Inventors: Tadashi Imai, Chiba (JP); Keisuke Yoshida, Aichi (JP); Kazunari Ueda, Aichi (JP); Toshiyuki Sudo, Tokyo (JP); Makoto Makishima, Saitama (JP)

(21) Appl. No.: 14/236,838

(22) PCT Filed: Aug. 3, 2012
(86) PCT No.: PCT/JP2012/069808

§ 371 Date: Feb. 3, 2014

(30) Foreign Application Priority Data
Aug. 12, 2011 (JP) 2011-177302

(51) Int. Cl. H05K 7/02; H05K 13/04

(52) U.S. Cl. CPC H05K 7/026; H05K 13/04
USPC 361/773; 29/832

(57) ABSTRACT

Provided is a tuner module including a tuner module main body involving a tuner board, a first leg projected from the tuner module main body and to be inserted into a first hole formed on a circuit board main body, a second leg projected from the tuner module main body and to be inserted into a second hole formed on the circuit board main body, the second leg being shorter than the first leg, and a signal terminal projected from the tuner board and to be inserted into a third hole formed on the circuit board main body, the signal terminal being shorter than the second leg. A taper is formed on at least tip end parts of the first leg and the second leg.

### 1. TECHNICAL FIELD

The present disclosure relates to a tuner module, a circuit board, and a method for assembling the circuit board, and particularly relates to a technology for automatically mounting a module device such as a tuner module on a circuit board.

### 2. BACKGROUND ART

A tuner in related art, as described in FIG. 1 of Patent Literature 1, for example, has a structured body of a metal can in which a circuit board 1 is cover by a chassis angle 8 and a shield lid 9, and connects a power source or signal to an external circuit from inside using a feedthrough capacitor 4, a pin header 25 shown in FIG. 9, or the like. Then, a main board 6 on which the tuner is to be mounted is connected with a chassis foot 8a, feedthrough capacitor 4, pin header 25 of the tuner, and thus, the tuner is fixed to and mounted on the main board 6. Such a tuner having many coils and chip parts built inside thereof, and having the shield lid 9 and a complex chassis angle metal part as shown in FIG. 7 has weighed hundreds of grams.

A condition for joining a chassis board (tuner main body) including the complex structured body (chassis angle, chassis foot or the like) as described above to the main board, and a weight due to a large number of metal parts and a large variety and number of parts built therein generally cause a mounting method by human hands. Therefore, manufacturing of the tuner has been in a circumstance where an operator for mounting the tuner is essential.

Further, from the connecting structure thereof, soldering is essential for connecting the chassis foot and the main board as an electrical connection method able to secure a high frequency-like contact resistance. However, since the chassis foot, which is also a part of the chassis angle, has a high thermal conductivity, a solder heating method with a high thermal capacity is needed in order to solder-join the chassis foot under a good soldering condition. For example, there is a dip method in which keeping away the parts from mounting on the side opposite to a tuner mounted face in the main board, entire the main board is passed through a solder layer. Additionally, it is necessary to use a reflow method in which a nozzle for locally spraying high temperature air is prepared to locally heat the above chassis foot.

In a soldering method of the dip method, a solder sprayed face (tuner non-mounted face) becoming a high temperature cannot be basically arranged thereon with the parts.

In addition, in the local reflow method, partially spraying or setting a nozzle position must be carried out depending on a shape of the tuner, and positions of the chassis foot and feedthrough capacitor. In other words, the nozzle must be reset depending on modification or model change of the tuner accompanied by change of the main board, leading to a problem of needing a lot of man-hours for changeover of a production line and the like.

On the other hand, advance in the IC technology of a high-frequency circuit in recent years has allowed most tuner circuits to be constituted by small ICs and also the tuner module of a form having those built therein to be increasingly downsized. As a result, the tuner module has been able to be also made thinner to much reduce a total weight of the tuner module. That is, a tuner module having a weight of 50 grams or less has been led to be developed to bring about a situation where adsorption load is possible by an automatic insertion device in terms of weight.

### CITATION LIST

### Patent Literature

Patent Literature 1: JP H10-22674A (FIG. 1, FIG. 9, etc.)

### SUMMARY OF INVENTION

### Technical Problem

However, as is apparent in the above example, a different form insertion terminal structure is given in spite of carrying out automatic insertion. That is, the pin header mounted on the main board engaged with the chassis angle as a press part and a part of the above chassis angle are made into a join portion of the main board. Generally, in case of assemblies fixed using the solder as above, gaps for soldering, reliability of solder-joining portion, and ease of assembling are respectively defined as the first design choice in many cases, and an appropriate gap is provided between components of individual join portions. Therefore, the terminal by which the tuner module finally assembled is joined to main board is to have a not small tolerance.

This tolerance, which is about 0±0.5 mm in a normal design, is not proper to the automatic insertion by the automatic insertion device.

The present disclosure is made in consideration of the above circumstance, and significantly improves work efficiency upon mounting the tuner module on the main board (circuit board main body).

### Solution to Problem

The present disclosure is configured to have a signal terminal which is electrically connected with a circuit board main body and at least one leg which is longer than a length of the signal terminal on a surface of a tuner module facing a circuit board main body.

According to one aspect of the present disclosure, when a tuner module main body having a tuner board therein is mounted on a circuit board main body, a tip end part with a taper being formed of a first leg projected from the tuner module main body is inserted into a first hole formed on the circuit board main body. Next, a tip end part with a taper being formed of a second leg projected from the tuner module main body is inserted into a second hole formed on the circuit board main body, the second leg being shorter than the first leg. Then, a signal terminal projected from the tuner board is inserted into a third hole formed on the circuit board main body, the signal terminal being shorter than the second leg.

### Advantageous Effects of Invention

According to at least one embodiment of the present disclosure, ease upon mounting a tuner module on a circuit board main body is enhanced to significantly improve work efficiency. Therefore, application thereof can be made to automatic insertion of the tuner module into the circuit board main body.

### BRIEF DESCRIPTION OF DRAWINGS

FIG. 1 is a block diagram illustrating an exemplary configuration of a tuner module mounting apparatus.

FIG. 2 is an outer appearance perspective view illustrating an exemplary tuner module according to one embodiment of the present disclosure.

FIG. 3 is a front view of the tuner module seen from an antenna connector side.

FIG. 4 is a back view of the tuner module seen from the opposite side of the antenna connector side.

FIG. 5 is an explanatory diagram illustrating a result of investigating whether or not able to read depending on a combination of a recognition mark and a color of an LED light source.

FIG. 6 is a perspective view illustrating a tuner module and a circuit board main body.

FIG. 7 is a transparent view of the tuner module mounted on the circuit board main body viewed from a rear side of the circuit board main body.

FIG. 8 is an explanatory diagram illustrating a gap between each of a guide terminal, reinforcement terminal, and signal terminal of the tuner module and a hole corresponding thereto on the circuit board main body.

A, B, and C of FIG. 9 are explanatory diagrams illustrating a process until the signal terminal of the tuner module is inserted into a hole of the circuit board main body.

FIG. 10 is a rear side view illustrating an exemplary positional relationship between a guide terminal, reinforcement terminal, and signal terminal of a tuner module according to a modification example of one embodiment of the present disclosure.

### DESCRIPTION OF EMBODIMENTS

Hereinafter, preferred embodiments of the present invention will be described in detail with reference to the appended drawings. Note that, in this specification and the drawings, elements that have substantially the same function and structure are denoted with the same reference signs, and repeated explanation is omitted.

An explanation will be given in the following order.

1. One embodiment (guide terminal: an example in which a guide terminal longer than a guide terminal signal terminal and reinforcement terminal is separated from the signal terminal)
1-1. Outline of tuner module mounting apparatus
1-2. Tuner module structure
1-3. Method for assembling circuit board (an example in which each of a guide terminal, reinforcement terminal and signal terminal of the tuner module is inserted into a hole corresponding thereto on the circuit board main body)
2. Modification example (guide terminal: an example in which all the signal terminals are surrounded by the guide terminal)

### 1. One Embodiment

### 1-1. Outline of Tuner Module Mounting Apparatus

First, an explanation will be given of an outline of a tuner module mounting apparatus for mounting a tuner module on a circuit board main body according to one embodiment of the present disclosure. In this embodiment, the tuner module is provided as an example of parts mounted on the circuit board main body, but not limited this example.

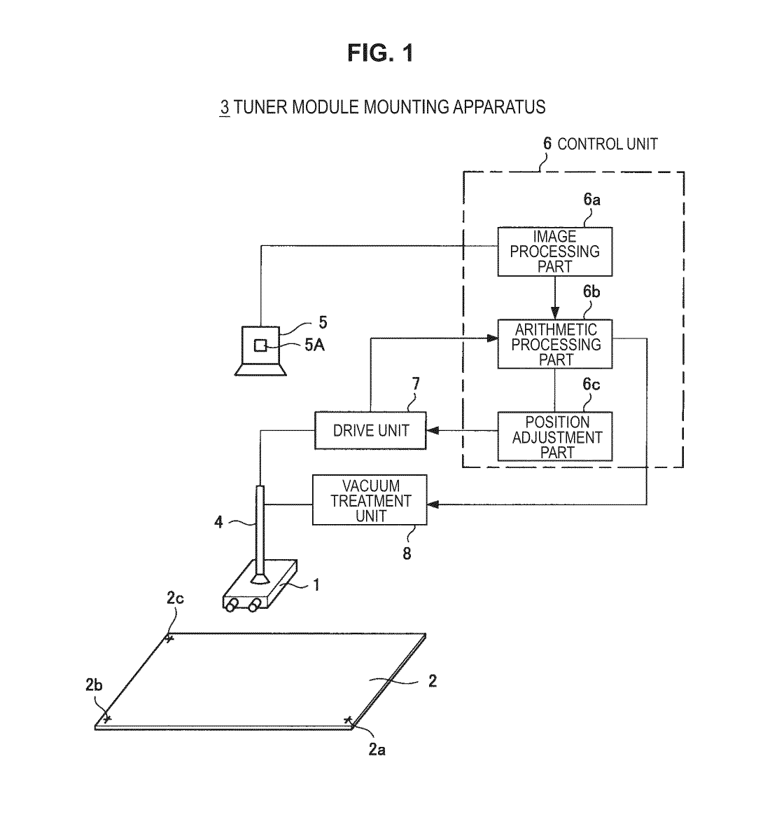

FIG. 1 is a block diagram illustrating an exemplary configuration of the tuner module mounting apparatus.

A tuner module mounting apparatus 3 is an apparatus for arranging a tuner module 1 at a specified position on a circuit board main body 2 to mount the tuner module 1 on the circuit board main body 2. The tuner module mounting apparatus 3 includes mainly a suction head 4, a camera 5, an illumination part 5A, a control unit 6, a drive unit 7, and a vacuum treatment unit 8.

The suction head 4 has a cylindrical hollow inside thereof, and is attached to an arm not shown in the figure which is connected with the drive unit 7. A tip end part of the suction head 4 is cause to abut a top face of the tuner module 1 and an abutted portion between the tip end part and the tuner module 1 is brought into a vacuum state by operating the vacuum treatment unit 8 such that the tip end part of the suction head 4 is stuck to the tuner module 1. The arm is worked in a state of the tip end part of the suction head 4 being stuck to the tuner module 1 to move the tuner module 1 to a destination position.

The camera 5, which is attached to the arm of the suction head 4 as an example, is an optical position measurement imaging unit. For example, images of the part (tuner module 1 in this example) stuck by the suction head 4 and the circuit board main body 2 are taken. The illumination part 5A illuminates an amount of light necessary for the camera 5 to take images of the tuner module 1 and circuit board main body 2. As for the illumination part 5A, a light emitting diode (LED) can be used as an example.

The control unit 6 includes mainly an image processing part 6a, an arithmetic processing part 6b, and a position adjustment part 6c.

The image processing part 6a performs a predetermined processing such as binarization on an image signal including information on a subject whose image is taken by the camera 5 before outputting to the arithmetic processing part 6b.

The arithmetic processing part 6b acquires current position information of the suction head 4 from a signal supplied from the drive unit 7. In addition, the arithmetic processing part 6b calculates a positional relationship between the circuit board main body 2 and the suction head 4 and a deviation amount thereof using the information from the image signal supplied from the image processing part 6a and the current position information of the suction head 4, and controls to output a result of the calculation to the position adjustment part 6c. Further, the arithmetic processing part 6b operates the vacuum treatment unit 8 to control the tip end part of the suction head 4 to be stuck to the tuner module 1.

The position adjustment part 6c outputs a drive signal to the drive unit 7 on the basis of the calculation result supplied from the arithmetic processing part 6b.

The drive unit 7 operates on the basis of a control signal from the position adjustment part 6c to work the arm coupled with the suction head 4.

The vacuum treatment unit 8 performs vacuuming on the basis of the control signal from the arithmetic processing part 6b to bring an atmosphere of the abutted portion between the tip end part of the suction head 4 and the part such as the tuner module 1 into the vacuum state.

Here, in this embodiment, the tip end part of the suction head 4 is stuck to the parts utilizing vacuum, but a suction part made of silicon may be provided to the tip end part to stick the parts by the silicon suction part. In that case, the vacuum treatment unit 8 is not needed.

An explanation will be given of the operation of the tuner module mounting apparatus 3 configured as above.

The control unit 6 of the tuner module mounting apparatus 3 controls the drive signal supplied to the drive unit 7 by instructing from the arithmetic processing part 6b to the position adjustment part 6c, and the tip end part of the suction head 4 is caused to abut a top face of a target tuner module 1 which exist at a certain position or housed in a tray (omitted from the figure).

At this time, the arithmetic processing part 6b of the control unit 6 controls the camera 5 to take images of the tuner module 1 and the tip end part of the suction head 4, and identifies the positional relationship both thereof using an image supplied from the image processing part 6a. In case where a location to be stuck on the tuner module 1 deviates from a position of the tip end part of the suction head 4, the arithmetic processing part 6b instructs the position adjustment part 6c to control the drive unit 7 to adjust the position of the suction head 4 and controls such that the tip end part of the suction head 4 abuts a defined location on the tuner module 1.

Then, the arithmetic processing part 6b of the control unit 6 operates the vacuum treatment unit 8 to stick the tip end part of the suction head 4 to the tuner module 1, and outputs the control signal to the drive unit 7 to work the arm coupled with the suction head 4 so as to move the tuner module 1 to a predetermined mounting position on the circuit board main body 2.

The arithmetic processing part 6b of the control unit 6 controls the camera 5 to take images of the tuner module 1 and the tip end part of the suction head 4, and mounts the tuner module 1 at a position for mounting on the circuit board main body 2 using the image supplied from the image processing part 6a. At this time, the arithmetic processing part 6b identifies the position for the tuner module 1 of the circuit board main body 2 with reference to alignment marks 2a to 2c provided to the circuit board main body 2 to mount the tuner module 1 on a defined correct position.

### 1-2. Tuner Module Structure

Next, an explanation will be given of a tuner module structure.

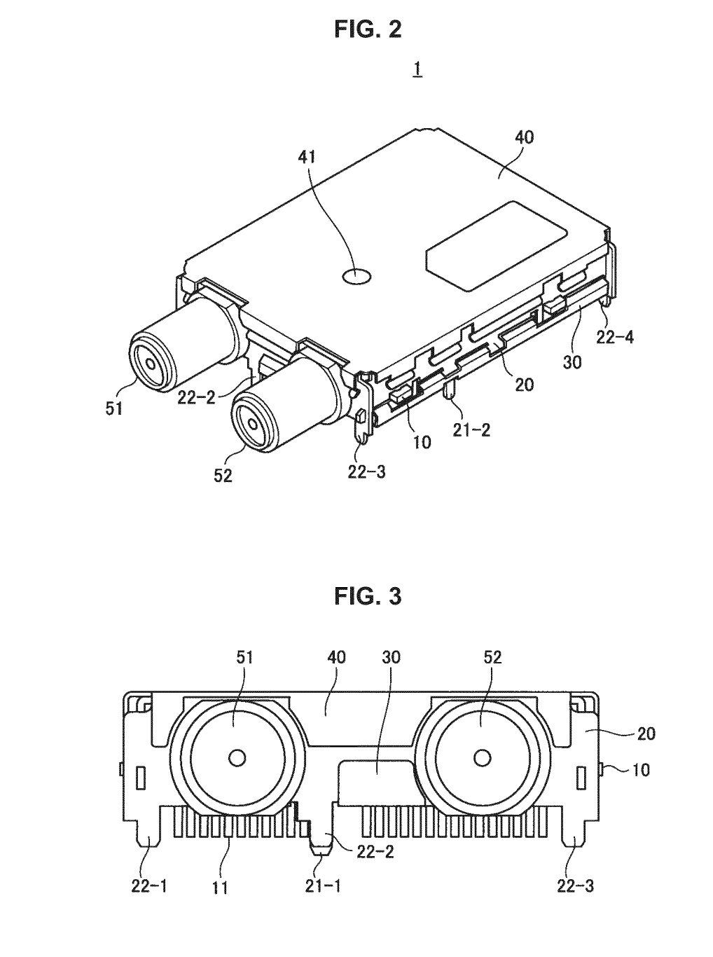

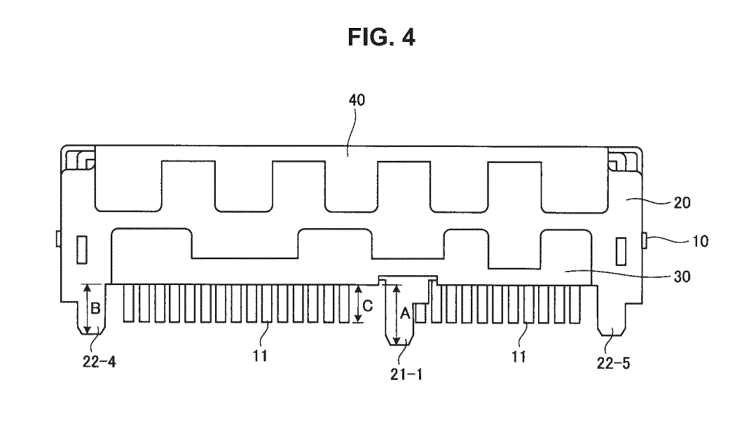

FIG. 2 is an outer appearance perspective view illustrating an exemplary tuner module according to one embodiment of the present disclosure. FIG. 3 is a front view of the tuner module 1 in FIG. 2 seen from an antenna connector side. FIG. 4 is back view of the tuner module 1 seen from the opposite side of the antenna connector.

The present disclosure is configured to have a signal terminal which is electrically connected with the circuit board main body 2 and at least one leg which is longer than a length of the signal terminal on a surface of the tuner module 1 facing the circuit board main body 2.

The tuner module 1 has biaxial antenna connectors 51 and 52 at the front thereof. The antenna connectors 51 and 52 are engaged with one lateral face of a tuner case 20 by a swage structure. The tuner case 20 contains a tuner board 10 inside thereof, a bottom face and top face of the tuner case 20 are configured to be covered by a base 30 and a cover 40, respectively. The tuner case 20, base 30, and cover 40 are each an exemplary tuner module main body.

The tuner board 10 has installed thereon an element group including an IC not shown in the figure which constitutes the tuner circuit and a pin header for connecting with the outside of the tuner module 1, and a ground of the tuner board 10 is electrically connected with the tuner case 20.

A top face of the cover 40 of the tuner module 1 is provided with a recognition mark 41 at a balance point of weight of whole the tuner module 1 (preferably, a center of gravity). The recognition mark 41 is provided at a predetermined position on the cover 40 seen from a direction in which the suction head 4 sucks up a main body of the tuner module 1, that is, with the main body of the tuner module 1 being seen from the top face. This recognition mark 41 is a target point which the suction head 4 of the tuner module mounting apparatus 3 aims at in a manner that keeps being horizontal and rises when contacting and sticking the tuner module 1, as well as is also an authentication point for optically reading a deviation tolerance of a stationary position of the tuner module 1 when sticking. This recognition mark 41 is drawn such that the position thereof can be read by reflecting a light emitted from the illumination part 5A such as the LED when detecting positions by the camera 5 for optical position measurement of the tuner module mounting apparatus 3.

Here, am explanation will be given of the recognition mark 41.

Generally, since metal is used for a material of the tuner case 20 and cover 40 of the tuner module 1, various reflections occur depending on an emission color the LED. For this reason, the recognition mark 41 is desirably marked with a color absorbing the light such as black. However, for example, the cover 40 is formed by bending a general tin plating steel material, called tin plate, in a press process, and therefore if a black mark is printed, a new process is needed separately from the press process. That induces a significant complication of an assembly of the circuit board and causes cost increase due to extension of a takt time. Therefore, in the present disclosure, a small protrusion which can be formed in the same process as a press work for the cover 40 is provided to the recognition mark 41 to allow works such as coloring to be removed.

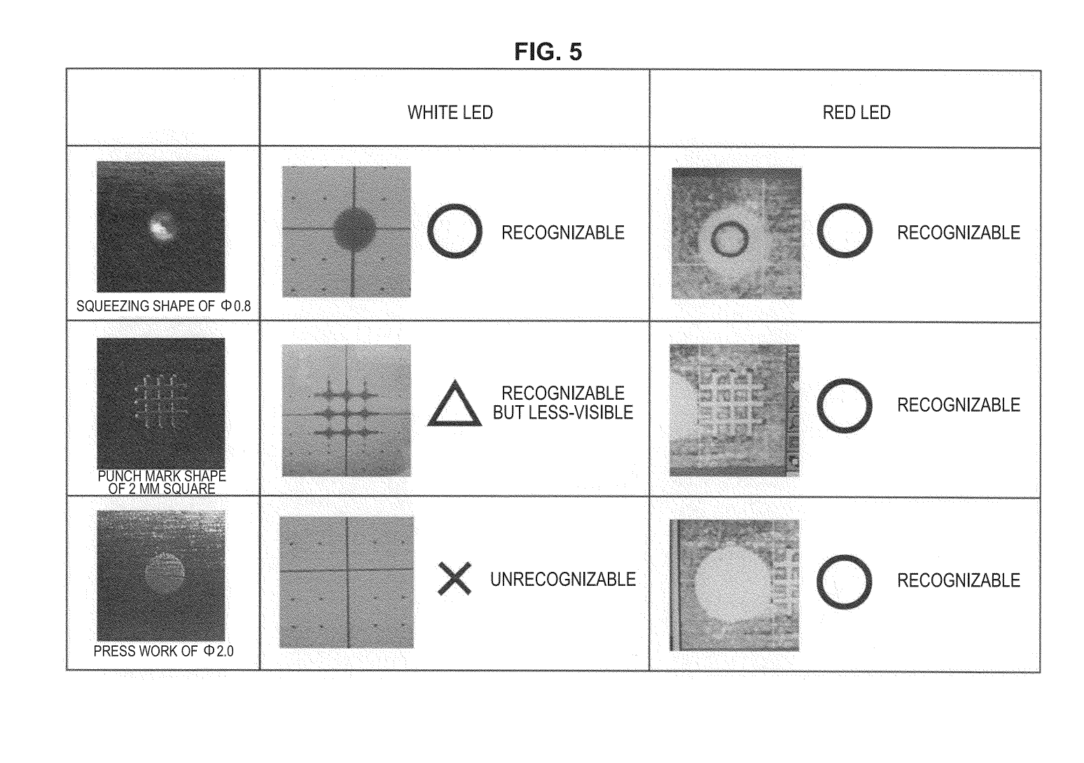

FIG. 5 is an explanatory diagram illustrating a result of investigating whether or not able to read depending on a combination of the recognition mark and a color of an LED light source.

This time, in the investigation, checked was whether or not a squeezing shape of (0.8, a punch mark shape (parallel crosses) of 2 mm square, and a press work (surface fabrication) of φ2.0 each can be read using white LED and red LED lights, as an example.

As a result, a small protrusion shape by squeezing work was able to be recognized in both cases of the while LED and the red LED. Particularly, it was found that even in the case of the red LED, recognition is very good compared with a multi punch mark type mark or a press type mark. This is attained by that a light obtained by reflecting the light from the LED light source is unlikely to reach toward the camera 5 located at a position close to an incident direction.

Next, referring to back view of the tuner module 1 seen from the opposite side of the antenna connector side in FIG. 4, an explanation will be given of a chassis foot structure suitable to the automatic insertion.

In this example, a pin header (omitted from the figure) having a plurality of signal terminals (pins) 11 is an integrated body mounted on the tuner board 10, but seems to be separated into two groups of the signal terminals 11 if seen from outside the tuner module 1.

Then, on a lower side of the tuner module 1 on which the circuit board main body 2 is mounted, arranged are a guide terminal 21-1 (leg: an exemplary first leg) having a length A, reinforcement terminals 22-4 and 22-5 having a length B (leg: an exemplary second leg), and the signal terminal 11 having a length C.

The guide terminal 21-1 is formed near the center on a back face with being projected from the tuner module main body (tuner case 20). The reinforcement terminals 22-4 and 22-5, each of which is a ground terminal for connecting with a ground potential of the circuit board main body 2 and reinforces a fixing strength of solder-joining between the signal terminal 11 and the circuit board main body 2, are formed near both ends of the back face with being projected from the tuner module main body (tuner case 20). The signal terminal 11 is formed and extended on the back face with being projected from the tuner board 10.

In the present disclosure, the length A, B, and C of the guide terminal, the reinforcement terminal and the signal terminal, respectively have a relationship as follows.

A>B≧C

However, which B>C or B=C is employed is preferably determined depending on a diameter of the signal terminal or shape of the tip end part thereof, and a clearance between signal terminal diameter and an insertion hole described later. Typically, so long as the clearance between the signal terminal diameter and the insertion hole is large, B=C or even a relationship like this may be thought to be all right. Note that if the length of the reinforcement terminal can be shortened matching the signal terminal, accordingly the length of the guide terminal can also be shortened to contribute to reduction of material cost.

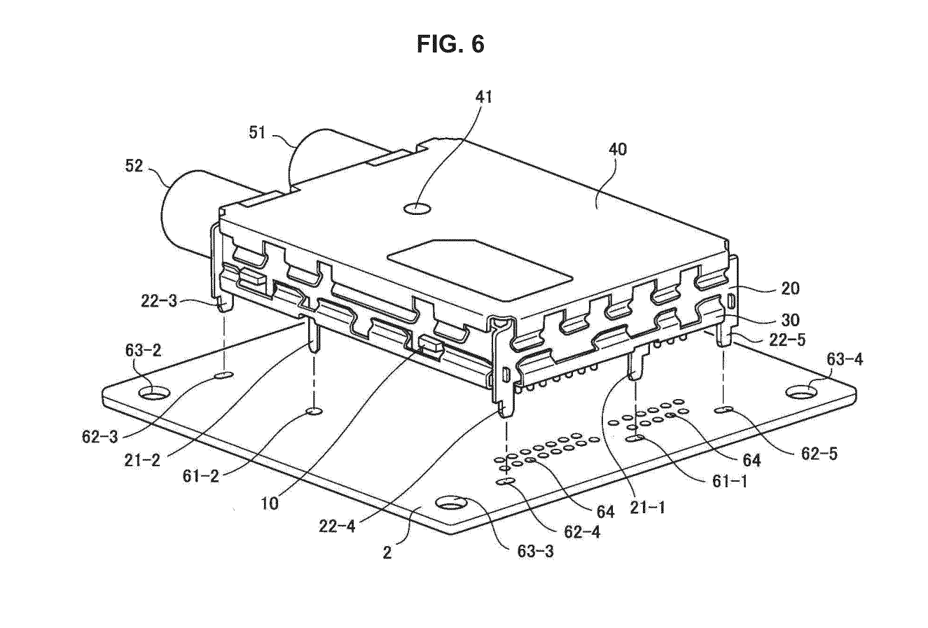

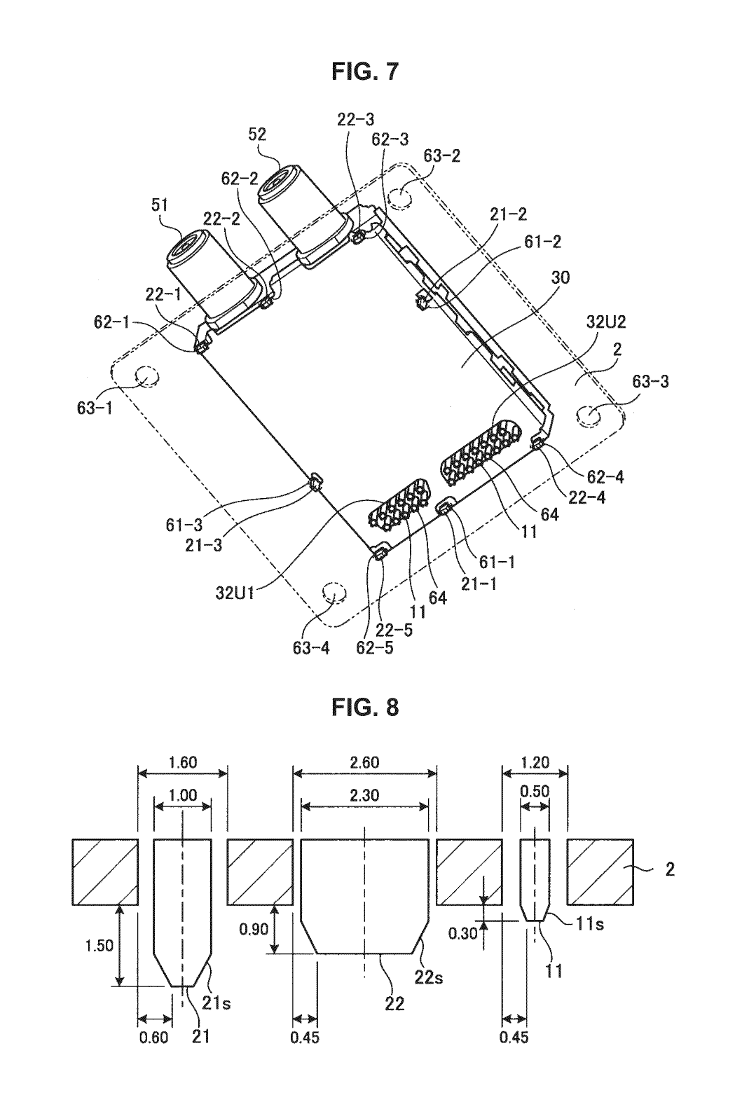

FIG. 6 is a perspective view illustrating the tuner module 1 and the circuit board main body 2. FIG. 7 is a transparent view of the tuner module 1 mounted on the circuit board main body 2 viewed from a rear side of the circuit board main body 2.

The circuit board main body 2, which constitutes a receiving circuit of a television set, mounted with the parts other than the tuner. Any circuit board main body is provided with a hole (first hole) for inserting the guide terminal, a hole (second hole) for inserting the reinforcement terminal, and a hole (third hole) for inserting the signal terminal which are provided to the above tuner module 1.

In the examples of FIG. 6 and FIG. 7, guide terminals 21-1 to 21-3, reinforcement terminals 22-1 to 22-5, and signal terminal 11 are projected on a side of the surface of the tuner module 1 facing the circuit board main body 2. In order to insert these respective terminals the circuit board main body 2 has formed thereon, correspondingly to arrangements of the respective terminals, insertion holes 61-1 to 61-3 for guide terminal, solder-joining holes 62-1 to 62-5 for reinforcement terminal, and a plurality of solder-joining holes 64 for signal terminal.

Here, the base 30 is provided with openings 32U1 and 32U2 and configured such that the signal terminals 11 of the pin header installed in the tuner board 10 are projected outside the base 30. Further, for example, holes 63-1 to 63-4 are formed for threadably attachment to the television set after mounting the tuner module 1.

Next, an explanation will be given of a function of each of the guide terminal, reinforcement terminal, and signal terminal.

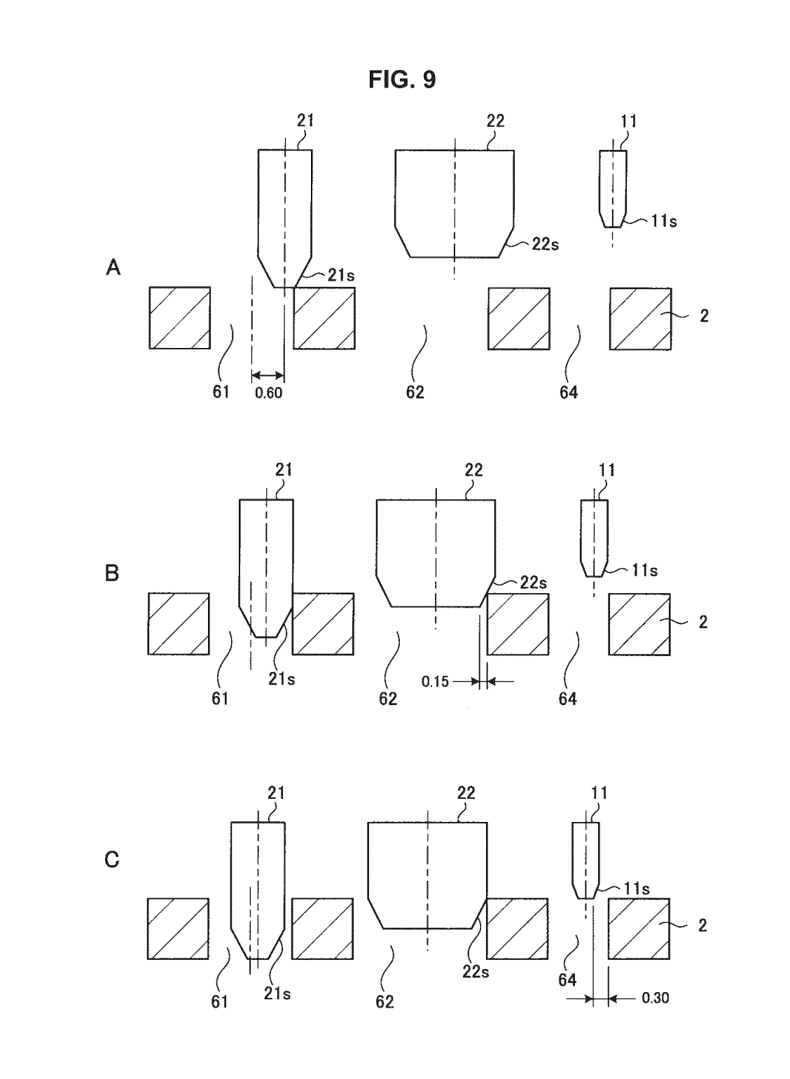

FIG. 8 is an explanatory diagram illustrating a gap (clearance) between each of the guide terminal, reinforcement terminal, and signal terminal of the tuner module 1 and a hole corresponding thereto on the circuit board main body. FIG. 8 is a simplified and schematic illustration for explaining each terminal function.

For the purpose of enhancing ease upon inserting each terminal of the tuner module 1 into each hole of the circuit board main body 2, a relationship between a diameter of each terminal and a diameter of each hole is set as below.

(1) Clearance between the guide terminal 21 and insertion hole . . . large

(2) Clearance between the reinforcement terminal 22 and the insertion hole . . . small: the signal terminal 11 may be well so long as the reinforcement terminal is finally inserted into a join hole at the same time as being inserted into the insertion hole, and may be set in the following range.

(3) Clearance between the signal terminal 11 and the join hole . . . more than the above (2) clearance

Here, as can be seen in FIG. 8, a tip end part of each terminal is formed tapered. For example, the guide terminal 21 has a tapered portion 21s formed thereon, as well as the reinforcement terminal 22 and the signal terminal 11 have formed a tapered portion 22s and a tapered portion 11s thereon, respectively. However, the tapered portions of the guide terminal 21 and reinforcement terminal 22 are needed, but the tapered portion of the signal terminal 11 is not necessarily needed. In addition, a shape of the tip end part may be curved instead of tapered, so long as not right angle nor acute angle.

In the example of FIG. 8, a thickness of the circuit board main body 2 is from 1.2 to 1.6 mm as an example. At this time, a clearance between the guide terminal 21 and the insertion hole is 0.30 mm, a distance between a cutout edge point of the tapered portion 21s and the insertion hole is 0.60 mm, and a length of a portion projected from the circuit board main body 2 is 1.50 mm.

Additionally, a clearance between the reinforcement terminal 22 and the insertion hole is 0.15 mm, a distance between a cutout edge point of the tapered portion 22s and the insertion hole is 0.45 mm, and a length of a portion projected from the circuit board main body 2 is 0.90 mm.

Moreover, a clearance between the signal terminal 11 and the insertion hole is 0.35 mm, a distance between a cutout edge point of the tapered portion 11s and the insertion hole is 0.45 mm, and a length of a portion projected from the circuit board main body 2 is 0.30 mm.

### 1-3. Method for Assembling a Circuit Board

A, B, and C of FIG. 9 are explanatory diagrams illustrating a process until the signal terminal 11 of the tuner module 1 is inserted into the solder-joining hole 64 of the circuit board main body.

The process is illustrated in which the tuner module 1 located at a position slightly deviated from a hole position goes down toward the circuit board main body 2 while the relationship among the guide terminal 21, reinforcement terminal 22, and signal terminal 11 in FIG. 8 described above is maintained.

When the suction head 4 of the tuner module mounting apparatus 3, which has flexibility to move right and left in some degree, sticks the recognition mark 41 and raises the tuner module 1, and goes down toward the circuit board main body 2, first the tapered portion 21s of the guide terminal 21 is brought into contact with an edge of the insertion hole 61 on the surface of the circuit board main body 2. The guide terminal 21 is introduced into inside of the insertion hole 61 along the tapered portion 21s to be slightly deviated in the left direction led to in the figure (FIG. 9A).

Next, when the reinforcement terminal 22 shorter than the guide terminal 21 is inserted in to the solder-joining hole 62 of the circuit board main body 2, with first the reinforcement terminal 22 being at a position deviated to the left side by the deviation of the above guide terminal 21, the tapered portion 22s is brought into contact with an edge of the solder-joining hole 62 on the surface of circuit board main body 2. The reinforcement terminal 22 is inserted into the solder-joining hole 62 along the tapered portion 22s, and inserted as well even if the clearance between the reinforcement terminal 22 and the solder-joining hole 62 (FIG. 9B).

Then, when finally the signal terminal 11 shorter than the reinforcement terminal 22 is inserted into the solder-joining hole 64 of the circuit board main body 2, positioning the signal terminal 11 is completed at the top face the solder-joining hole 64 (FIG. 9C) by being dragged with the above movement of the guide terminal 21 and reinforcement terminal 22.

At this time, the clearance more than sticking accuracy of the tuner module 1 may be given between the guide terminal 21 and the insertion hole 61. In addition, the reinforcement terminal 22 configured from the tuner case 20 the same part as the guide terminal 21 may be provided with as small solder-joining hole 62 as possible such that the clearance of only the deviation amount the guide terminal 21 cannot correct is given. On the other hand, the signal terminal 11 is inserted into the solder-joining hole 64 having a size added with an allowance which includes all of an insertion tolerance between the pin header and the tuner board 10, an assembly tolerance between the tuner board 10 and the tuner case 20, and the clearance between the above reinforcement terminal 22 and the solder-joining hole 62.

According to this embodiment described above, ease upon mounting the tuner module 1 on the circuit board main body 2 is enhanced to significantly improve work efficiency. Therefore, application thereof can be made to automatic insertion of the tuner module 1 into the circuit board main body 2, that is, a tuner module mounting process of the tuner module mounting apparatus.

### 2. Modification Example

This modification example is a modification example relating to arrangement of the guide terminal according to one embodiment.

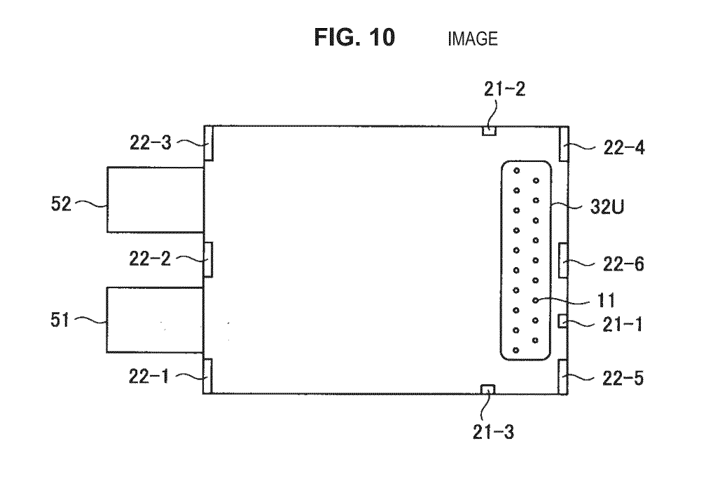

FIG. 10 is a rear side view illustrating an exemplary positional relationship between the guide terminal, reinforcement terminal, and signal terminal of the tuner module according to a modification example of one embodiment of the present disclosure.

As shown in FIG. 10, a plurality of guide terminals are preferably arranged to surround the signal terminal 11 for attaching the board with the theoretical largest production tolerance. It is beneficial that at least all the signal terminal 11 are configured to be surrounded by a plurality of guide terminals 21-1 to 21-3, and the reinforcement terminals 22-1 to 22-6 and all the signal terminals 11 are arranged at approximately equal intervals.

In the example of FIG. 10, three guide terminals are arranged such that all the signal terminals 11 fall within a range of vertical and horizontal projection widths (Feret diameter) of the relevant three guide terminals.

In the arrangement of the guide terminal, positions of a plurality of guide terminals with respect to the signal terminal may be set depending on an area of the surface of the tuner module 1 facing the circuit board main body 2 (or weight balance).

For example, in one embodiment as shown in FIG. 7, the guide terminal 21-2 of three guide terminals 21-1 to 21-3 is arranged at a position closer to the antenna connector side than the signal terminal 11 side. The arrangement of the guide terminal 21-2 to the antenna connector side insertion ease of the reinforcement terminal as well as the signal terminal with respect to the hole is enhanced, allowing enhancement of mounting ease of the tuner module 1 with respect to the circuit board main body 2.

Here, the above modification example shows a preferable example in which a plurality of guide terminals are arranged, but even if at least one guide terminal is provided only, the insertion ease of the reinforcement terminal as well as the signal terminal is enhanced, and therefore the mounting ease of the tuner module is enhanced. Moreover, the reinforcement terminal may be at least one or more similarly.

In addition, the reinforcement terminal, after inserted into the insertion hole of the circuit board main body, is solder-joined to the relevant circuit board main body, but the guide terminal also, after inserted into the insertion hole of the circuit board main body, may be solder-joined the relevant circuit board main body. In other words, a part of the respective functions of the guide terminal and reinforcement terminal is commonly used. In such a case, the total number of the guide terminals and reinforcement terminals can be reduced, allowing simplification of the tuner case structure and reduction of material cost.

As described previously, in technological thought of the present disclosure, a configuration may be such that provided on the surface of the tuner module facing the circuit board main body are the signal terminal electrically connected with the relevant circuit board main body and at least one leg longer than the length of the signal terminal. In other words, the guide terminal and reinforcement terminal of the above described tuner module may be a plurality terminals (legs) having the same length longer than the signal terminal. Then, this leg is used to bring and insert the signal terminal into a predetermined hole of the circuit board main body, and after the insertion, the relevant leg is solder-joined to the circuit board main body. Alternatively, as the configuration of the tuner module, one or more guide terminals or reinforcement terminals longer than at least one signal terminal may be included to secure the ease of insertion into the circuit board main body.

Additionally, the present technology may also be configured as below.

(1)

A tuner module including:

a tuner module main body involving a tuner board;

a first leg projected from the tuner module main body and to be inserted into a first hole formed on a circuit board main body;

a second leg projected from the tuner module main body and to be inserted into a second hole formed on the circuit board main body, the second leg being shorter than the first leg; and

a signal terminal projected from the tuner board and to be inserted into a third hole formed on the circuit board main body, the signal terminal being shorter than the second leg,

wherein a taper is formed on at least tip end parts of the first leg and the second leg.

(2)

The tuner module according to (1), wherein a difference between a diameter of the first leg and a diameter of the first hole is larger than a difference between a diameter of the second leg and a diameter of the second hole.

(3)

The tuner module according to (2), wherein a difference between a diameter of the signal terminal and a diameter of the third hole is equal to or larger than a difference between the diameter of the second leg and the diameter of the second hole.

(4)

The tuner module according to any one of (1) to (3), wherein positions of a plurality of first legs with respect to the signal terminal are set depending on an area of a surface of the tuner module main body facing the circuit board main body.

(5)

The tuner module according to (4), wherein the plurality of first legs are arranged such that the signal terminal fall within a range of vertical and horizontal projection widths of the plurality of first legs.

(6)

The tuner module according to (5), wherein at least one of the plurality of first legs is arranged at a position with respect to the signal terminal at an interval larger than a distance between other first legs and the signal terminal.

(7)

The tuner module according to any one of (1) to (6).

wherein the signal terminal, after being inserted into the third of the circuit board main body, is solder-joined to the circuit board main body, and

wherein the second leg, after inserted into the second hole of the circuit board main body, is solder-joined to the circuit board main body.

(8)

The tuner module according to (7), wherein the first leg, after being inserted into the first hole of the circuit board main body, is solder-joined to the circuit board main body.

(9)

The tuner module according to any one of (1) to (8), wherein a recognition mark causing a tip end part of a suction head to abut is provided on a top face of the tuner module main body.

(10)

The tuner module according to (9), wherein the recognition mark is provided at a center of gravity of the tuner module main body with the tuner module main body being seen from the top face.

(11)

A tuner module including:

a tuner module main body involving a tuner board;

at least one first leg projected from the tuner module main body and to be inserted into a hole formed on a circuit board main body; and

a signal terminal projected from the tuner board and to be inserted into a hole other than the hole formed on the circuit board main body, the signal terminal being shorter than the leg.

wherein a recognition mark as a target upon sticking to the tuner module main body is provided on a top face of the tuner module main body, and a taper is formed on at least a tip end part of the leg.

(12)

A circuit board including:

a circuit board main body; and

a tuner module including
a tuner module main body involving a tuner board.
a first leg projected from the tuner module main body and inserted into a first hole formed on the circuit board main body,
a second leg projected from the tuner module main body and inserted into a second hole formed on the circuit board main body, the second leg being shorter than the first leg, and
a signal terminal projected from the tuner board and inserted into a third hole formed on the circuit board main body, the signal terminal being shorter than the second leg,
wherein a taper is formed on at least tip end parts of the first leg and the second leg.
   (13)

A circuit board including:

a circuit board main body;

a tuner module main body involving a tuner board;

at least one first leg projected from the tuner module main body and to be inserted into a hole formed on the circuit board main body; and

a signal terminal projected from the tuner board and to be inserted into a hole other than the hole formed on the circuit board main body, the signal terminal being shorter than the leg,

wherein a recognition mark as a target upon sticking to the tuner module main body is provided on a top face of the tuner module main body, and a taper is formed on at least a tip end part of the leg.

(14)

A method for assembling a circuit board including:

when a tuner module main body involving a tuner board is mounted on a circuit board main body, inserting a tip end part with a taper being formed of a first leg projected from the tuner module main body into a first hole formed on the circuit board main body;

inserting a tip end part with a taper being formed of a second leg projected from the tuner module main body into a second hole formed on the circuit board main body, the second leg being shorter than the first leg; and

inserting a signal terminal projected from the tuner board into a third hole formed on the circuit board main body, the signal terminal being shorter than the second leg.

Additionally, in this description, a processing step describing a time series processing includes a processing performed in time series along the described order of course, and also includes, even if not necessarily processed in time series, a processing performed in parallel or individually (e.g., parallel processing or processing by object).

The present disclosure is not limited to the above described embodiments, and other various modification examples and application examples may be obviously made unless departing from the substance described in the claims.

In other words, the examples of the above described embodiments are preferable and specific examples of the present disclosure and the technologically preferable various limits are given. However, the technical scope of the present disclosure, unless otherwise limitation on the present disclosure is specifically described in the explanations, is not limited to these embodiments. For example, use material and used amount thereof, processing time, processing order, and numerical condition of each parameter or the like which are described below are merely preferable examples, and a size, shape, and arrangement relationship in the figures used for the explanation are also schematic.

For example, in the above described embodiments, the tuner module is constituted by tuner case having the tuner board built therein, and the base and cover covering the bottom face and top face of the relevant tuner case. On the other hand, the tuner module may be a simple configuration not using the base and cover.

For example, the tuner case is formed into a frame-shaped cuboid with one surface side (bottom face side) being opened, and the tuner board is housed in a housing space defined by the frame-shaped cuboid so as to cover thereof. In other words, the tuner case is formed into approximately an frame shape including a rectangular base face part which has a surface parallel with the tuner board and is a top face in a fixed state, and four lateral face parts which are formed at edges of the base face part and each have a surface substantially perpendicular to the relevant base face part. This base face part has a function as the cover in one embodiment and recognition mark is provided at an appropriate position on the top face of the base face part.

This tuner case can be formed by processing one metal plate. First, two edge faces facing each other of the base face part are bent at rights toward the tuner board side to form two lateral face parts facing each other. Next, other two edge faces of the base face part are bent at rights toward the tuner board side to form two lateral face parts facing each other, and then, the approximately frame-shaped tuner case is formed. Then, a first leg and a second leg are formed at the edge of any of the lateral face parts on the circuit board main body side, and these legs are used to carry out the mounting and fixing on the circuit board main body. As an example of the tuner module having such a configuration, that described in the description and drawings of JP 2010-165131A can be cited.

### REFERENCE SIGNS LIST

1 tuner module
2 circuit board main body
2a to 2c alignment mark
3 tuner module mounting apparatus
4 suction head
5 camera
5A illumination part
6 control unit
6a image processing part
6b arithmetic processing part
6c position adjustment part
7 drive unit
8 vacuum treatment unit
10 tuner board
11 signal terminal
20 tuner case
21-1 to 21-3 guide terminal
21s tapered portion
22, 22-1 to 22-6 reinforcement terminal
22s tapered portion
30 base
32U, 32U1, 32U2 opening
40 cover
41 recognition mark
51, 52 antenna connector
61, 61-1 to 61-5 insertion hole
62, 62-1 to 62-3 solder-joining hole
63-1 to 63-4 hole
64 solder-joining hole

1. A tuner module comprising:
a tuner module main body involving a tuner board;
a first leg projected from the tuner module main body and to be inserted into a first hole formed on a circuit board main body;
a second leg projected from the tuner module main body and to be inserted into a second hole formed on the circuit board main body, the second leg being shorter than the first leg; and
a signal terminal projected from the tuner board and to be inserted into a third hole formed on the circuit board main body, the signal terminal being shorter than the second leg,
wherein a taper is formed on at least tip end parts of the first leg and the second leg.

2. The tuner module according to claim 1, wherein a difference between a diameter of the first leg and a diameter of the first hole is larger than a difference between a diameter of the second leg and a diameter of the second hole.

3. The tuner module according to claim 2, wherein a difference between a diameter of the signal terminal and a diameter of the third hole is equal to or larger than a difference between the diameter of the second leg and the diameter of the second hole.

4. The tuner module according to claim 3, wherein positions of a plurality of first legs with respect to the signal terminal are set depending on an area of a surface of the tuner module main body facing the circuit board main body.

5. The tuner module according to claim 4, wherein the plurality of first legs are arranged such that the signal terminal fall within a range of vertical and horizontal projection widths of the plurality of first legs.

6. The tuner module according to claim 5, wherein at least one of the plurality of first legs is arranged at a position with respect to the signal terminal at an interval larger than a distance between other first legs and the signal terminal.

7. The tuner module according to claim 1,
wherein the signal terminal, after being inserted into the third hole of the circuit board main body, is solder-joined to the circuit board main body, and
wherein the second leg, after inserted into the second hole of the circuit board main body, is solder-joined to the circuit board main body.

8. The tuner module according to claim 7, wherein the first leg, after being inserted into the first hole of the circuit board main body, is solder-joined to the circuit board main body.

9. The tuner module according to claim 1, wherein a recognition mark causing a tip end part of a suction head to abut is provided on a top face of the tuner module main body.

10. The tuner module according to claim 9, wherein the recognition mark is provided at a center of gravity of the tuner module main body with the tuner module main body being seen from the top face.

11. A tuner module comprising:
a tuner module main body involving a tuner board;
at least one first leg projected from the tuner module main body and to be inserted into a hole formed on a circuit board main body; and
a signal terminal projected from the tuner board and to be inserted into a hole other than the hole formed on the circuit board main body, the signal terminal being shorter than the leg,
wherein a recognition mark as a target upon sticking to the tuner module main body is provided on a top face of the tuner module main body, and a taper is formed on at least a tip end part of the leg.

12. A circuit board comprising:
a circuit board main body; and
a tuner module including
a tuner module main body involving a tuner board,
a first leg projected from the tuner module main body and inserted into a first hole formed on the circuit board main body,
a second leg projected from the tuner module main body and inserted into a second hole formed on the circuit board main body, the second leg being shorter than the first leg, and
a signal terminal projected from the tuner board and inserted into a third hole formed on the circuit board main body, the signal terminal being shorter than the second leg,
wherein a taper is formed on at least tip end parts of the first leg and the second leg.

13. A circuit board comprising:
a circuit board main body;
a tuner module main body involving a tuner board;
at least one first leg projected from the tuner module main body and to be inserted into a hole formed on the circuit board main body; and
a signal terminal projected from the tuner board and to be inserted into a hole other than the hole formed on the circuit board main body, the signal terminal being shorter than the leg,
wherein a recognition mark as a target upon sticking to the tuner module main body is provided on a top face of the tuner module main body, and a taper is formed on at least a tip end part of the leg.

14. A method for assembling a circuit board comprising:
when a tuner module main body involving a tuner board is mounted on a circuit board main body, inserting a tip end part with a taper being formed of a first leg projected from the tuner module main body into a first hole formed on the circuit board main body;
inserting a tip end part with a taper being formed of a second leg projected from the tuner module main body into a second hole formed on the circuit board main body, the second leg being shorter than the first leg; and
inserting a signal terminal projected from the tuner board into a third hole formed on the circuit board main body, the signal terminal being shorter than the second leg.
